(19) United States
(12) Patent Application Publication
(10) Pub. No.: US 2026/0079221 A1
(43) Pub. Date: Mar. 19, 2026

(54) Sample Loading in a Magnetic Resonance System

(71) Applicant: Quantum Valley Investment Fund LP, Waterloo (CA)

(72) Inventors: Donald Edward Carkner, Waterloo (CA); Derek Blair Poirier Thompson, Waterloo (CA); Troy W. Borneman, Waterloo (CA)

(73) Assignee: Quantum Valley Investment Fund LP, Waterloo (CA)

(21) Appl. No.: 19/394,072

(22) Filed: Nov. 19, 2025

Related U.S. Application Data
(63) Continuation of application No. PCT/CA2024/050688, filed on May 23, 2024.
(60) Provisional application No. 63/504,143, filed on May 24, 2023.

(51) Int. Cl. G01R 33/30; G01R 33/31

(52) U.S. Cl. CPC G01R 33/307; G01R 33/305; G01R 33/31

(57) ABSTRACT

In a general aspect, a sample is loaded in a magnetic resonance system. In some aspects, a magnetic resonance system includes a primary magnet that generates a primary magnetic field and a resonator that defines a sample region in the primary magnetic field. A sample transfer arm includes a first end configured to couple to a sample holder. A centering device is disposed around the sample transfer arm. A seat defines an opening. An actuator system moves the centering device to mate with the seat. Mating the centering device with the seat aligns the sample holder with the opening. The sample transfer arm is moved to transfer the sample holder from a sample loading region, through the opening, towards the sample region.

### CROSS-REFERENCE TO RELATED APPLICATIONS

This patent application claims priority to U.S. Provisional Patent Application No. 63/504,143, filed on May 24, 2023 and titled “Sample Loading in a Magnetic Resonance System.” The above-referenced priority application is hereby incorporated by reference.

### BACKGROUND

The following description relates to loading samples in magnetic resonance systems.

Magnetic resonance systems are used to study various types of samples and phenomena. A resonator manipulates the spins in a sample by producing a magnetic field at or near the spins' resonance frequencies. In some cases, the resonator detects the spins based on a voltage induced by the precessing spins.

### DESCRIPTION OF DRAWINGS

FIG. 1 is a schematic diagram of an example magnetic resonance system;

FIG. 2 is a schematic diagram of an example sample loading system of a magnetic resonance system with a sample transfer device in a first position.

FIG. 3 is a schematic diagram of the example sample loading system of FIG. 2 with the sample transfer device in a second position.

FIG. 4 is a schematic diagram of the example sample loading system of FIG. 2 with the sample transfer device in a third position.

FIG. 5 is a cross-sectional view of an example magnetic resonance system showing a sample transfer device in a first position.

FIG. 6 is a cross-sectional view of the example magnetic resonance system of FIG. 5 showing the sample transfer device in a second position with a valve closed.

FIG. 7 is a cross-sectional view of the example magnetic resonance system of FIG. 5 showing the sample transfer device in the second position with a valve open.

FIG. 8 is a cross-sectional view of the example magnetic resonance system of FIG. 5 showing the sample transfer device in a third position.

FIG. 9 is a flow diagram of a process for loading a sample in a magnetic resonance system.

### DETAILED DESCRIPTION

In some aspects of what is described, magnetic resonance samples are transferred to a target position, for example, to a sample region adjacent to a resonator in a primary magnetic field. Aspects of the process can be automated, for example, by a control system that controls one or more actuators. In some examples, a sample transfer device is driven by an actuator to engage a sample holder in a sample loading region of the magnetic resonance system, and an alignment member connected to the sample transfer device is driven by an actuator to mate with a seat. Mating the alignment member with the seat aligns the sample holder with a port, so that the sample holder can be moved through the port toward the target position. The alignment may prevent unwanted mechanical contact between components during movement (e.g., between the sample holder and the seat) that could damage components or cause wear over time.

In some implementations, the target position for the sample resides in an environment that is similar to the environment of the sample loading region, for example, at room temperature and pressure or another type of environment. In some implementations, the target position for the sample resides in a controlled environment (e.g., vacuum environment, a cryogenic environment, or both). Accordingly, the magnetic resonance system may include one or more transition zones or stages between the room temperature and pressure environment of the sample loading region and the controlled environment of the target position.

In some implementations, the sample holder is moved from the sample loading region, through the port, into an interior volume, also referred to as a load lock, between the sample loading region and the target position. In some cases, the interior volume becomes sealed when the sample holder is inserted into the interior volume. For instance, the alignment member may include one or more seals (e.g., O rings, compression fittings, etc.) that contact the seat and the sample transfer device to inhibit fluid flow between the sample loading region and the interior volume. In various implementations, the fluid may be a liquid such as, for example liquid nitrogen or a gas such as for example, air, gaseous nitrogen, or other gases. While sealed, the interior volume can be pumped to a pressure (e.g., a vacuum pressure) that more closely matches the environment of the target position. In some cases, the interior volume is pumped at a high rate to reduce the amount of time that the sample holder resides in the load lock, for instance, to reduce or avoid heating of a cold sample. A port between the interior volume and the environment of the target position can then be opened, and the sample holder can be transferred through the port toward the target position. For instance, the sample transfer device can be driven by the actuator to move the sample holder through the port.

After the sample has been positioned in the sample region, the magnetic resonance system can interact with the sample, for example, to perform magnetic resonance experiments and obtain magnetic resonance measurements from the sample. After such operation, the magnetic resonance sample can be removed from the sample region. For example, the sample holder can be moved from the target position back to the sample loading region by the sample transfer device moving in the opposite direction relative to the sample loading process.

In some implementations, a magnetic resonance system includes a primary magnet that generates a primary magnetic field and a resonator that defines a sample region in the primary magnetic field. A sample transfer arm couples to a sample holder that holds at least one magnetic resonance sample. The sample holder can be a cartridge, a cassette, a tubular device, or another type of structure. The magnetic resonance system may include additional components that operate to move the sample holder to a selected position relative to a resonator of the magnetic resonance system; for example, the magnetic resonance system may include an actuator, a control system, or a combination of these and other components. In some instances, the magnetic resonance system moves the sample holder from a sample loading environment, for example at room temperature and pressure, into a controlled environment near the resonator in the primary magnetic field of the magnetic resonance system.

In some implementations, the magnetic resonance system includes a centering device disposed around (e.g., slidably secured around) the sample transfer arm. The centering device is configured to interface with a seat that defines an opening. Interaction of the centering device with the seat causes the sample transfer arm and the sample holder to be aligned with the opening. In some examples, an axis of the sample transfer arm that defines the path of the sample holder becomes aligned with the opening so that the sample holder passes through the opening when the sample transfer arm is driven by the actuator toward the sample region. In various implementations, the sample holder is aligned with the sample region with micron precision over the length of travel of the sample transfer device.

In some instances, magnetic resonance measurements may be performed in a cryogenic environment or at partial-vacuum pressures. In such implementations, a load lock assembly may be coupled to the seat such that the interior volume of the load lock assembly is accessed via the opening. When the centering device interacts with the seat, a seal is created that allows an internal temperature and pressure of the load lock assembly to be adjusted closer to an internal temperature and pressure of a chamber that houses the resonator.

Aspects of the systems and techniques described here can be implemented in various types of magnetic resonance systems. For example, a sample changer apparatus may be implemented in a nuclear magnetic resonance (“NMR”) system, an electron spin resonance (“ESR”) or electron paramagnetic resonance (“EPR”) system, or another type of magnetic resonance system. As another example, all or part of a sample changer apparatus may be deployed on a probe for a magnetic resonance system, or a sample changer apparatus can be deployed in a probeless magnetic resonance system. In some cases, a sample holder can be adapted to hold liquid samples, solid samples, liquid crystal samples, spin-labeled protein samples, other biological samples (e.g., blood samples, urine samples, saliva samples, etc.), or other types of samples to be measured or otherwise analyzed by a magnetic resonance system. As another example, a sample changer apparatus may be deployed with a resonator package that operates in a cryogenic environment. In some cases, the cryogenic environment is liquid helium temperatures (e.g., approximately 4 Kelvin), liquid nitrogen temperatures (e.g., approximately 77 Kelvin), or another cryogenic temperature. In some cases, the cryogenic environment includes a dry cryostat. In some cases, the cryogenic environment can be implemented with or without the use of liquid cryogens, for example, as a continuous flow helium or nitrogen cryostat (e.g., 4-300 Kelvin), as a variable temperature pulsed-tube refrigerator (e.g., 3.5-300 Kelvin), a pumped helium cryostat (e.g., 1-10 Kelvin), a helium-3 refrigerator (e.g., 250-400 milliKelvin), a dilution refrigerator (e.g., 5-100 milliKelvin), or another type of system or combination of systems. The resonator can be, for example, a microstrip, a cavity, a coil, a coplanar waveguide, or another type of resonator for magnetic resonance systems. Additionally, the resonator could be, for example, a rectangular cavity resonator, a cylindrical cavity resonator, a dielectric resonator, a loop gap resonator, or any lumped element resonator.

In some cases, the systems and techniques presented here can be deployed in connection with various cryogenic systems, including, for example, compact closed-cycle systems, open-cycle, liquid cryogen systems and others. In some cases, the systems and techniques presented here can be deployed in connection with various probes, including compact probe designs that may enable low-noise cryogenic amplifiers and other cryogenic electronics to be used in a variety of configurations. In some cases, the techniques and systems described here can be deployed in connection with continuous wave (CW) magnetic resonance (e.g., using CW ESR spectroscopy or CW NMR spectroscopy methodology), pulsed magnetic resonance (e.g., using pulsed ESR spectroscopy or pulsed NMR spectroscopy methodology), or a combination of these and other MR regimes.

In some implementations, the systems and techniques described here can provide technical advantages and improvement over existing technologies. As an example, the systems and techniques here may improve system efficiency, for instance, by reducing the amount of time that is required to change samples in a magnetic resonance system. As another example, the systems and techniques here may improve the quality of magnetic resonance data and measurements obtained by a magnetic resonance system, for instance, by allowing precise positioning of samples in the controlled operating environment of the resonator package. Such precise positioning optimizes a sample filling factor an improves an RF or microwave field homogeneity. This improves sensitivity and pulse sequence fidelity. As another example, samples can be moved with high precision to minimize or avoid unwanted mechanical contact between components that could cause damage or wear. As another example, samples can be moved with higher speed to minimize or avoid unwanted heat transfer to a sample; for instance, automation and mechanical efficiencies can allow cold samples to be transferred into a cryogenic environment in less time, which minimizes disturbance to the desired thermodynamic state of the sample. Other improvements and advantages may be achieved in some cases.

Aspects of the systems and techniques described here can be adapted for various types of applications. For example, the systems and techniques described here may be used for structural biology measurements, for instance, to measure structural properties of proteins or protein complexes in a biological sample (e.g., a blood sample, a urine sample, or another type of biological sample). Such measurements can be useful in clinical applications (e.g., diagnostics, treatments, etc.), pharmaceutical drug discovery/development and understanding the structure and function of membrane proteins, and other applications.

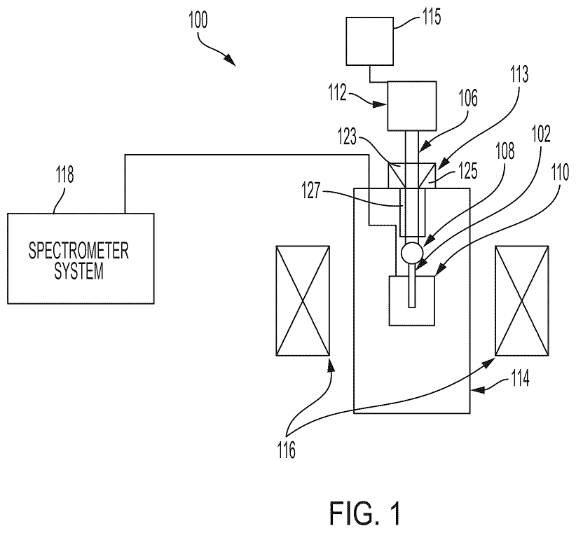

FIG. 1 is a schematic diagram of an example magnetic resonance system 100. In various implementations the magnetic resonance system 100 may be utilized, for example, in nuclear magnetic resonance (“NMR”) spectroscopy, electron spin resonance (“ESR”) or electron paramagnetic resonance (“EPR”) spectroscopy, nuclear quadrupole resonance spectroscopy (“NQR”), or other applications. The magnetic resonance system 100 includes a sample holder 102 that holds one or more magnetic resonance samples. In various implementations, the sample holder 102 is constructed from a material that has favorable dielectric properties (e.g., low tangent loss) and that is suitable for cryogenic temperatures. In various implementations, the sample holder 102 may be constructed, for example, of quartz, sapphire, borosilicate glass, or other similar material. In the example shown in FIG. 1, the sample holder 102 is coupled to a first end of a sample transfer device 106 via an attachment mechanism 108. The sample transfer device 106 can move the sample holder 102 and position the sample holder 102 relative to a resonator 110 in the primary magnetic field of the magnetic resonance system 100. In various implementations, the resonator 110 may be enclosed in a resonator housing or another type of resonator package.

In the example shown in FIG. 1, a second end of the sample transfer device 106 is coupled to an actuator system 112. In operation, the actuator system 112 drives movement of the sample transfer device 106 and may, in various implementations include, for example, a single-degree-of-freedom linear actuator that translates the sample transfer device 106 in a linear fashion along an axis of the sample transfer device 106. Examples of single-degree-of-freedom linear actuators include, for example, a mechanical linear actuator, an electro-mechanical linear actuator, a linear motor, a piezoelectric actuator, a twisted and coiled polymer (“TCP”) actuator, a hydraulic actuator, a pneumatic actuator, or other type of linear actuator. In various implementations, the actuator system 112 could include for example, a multi-degree-of-freedom actuator such as, for example a two-degree-of-freedom actuator that moves the sample transfer device 106 in a linear fashion along two independent (e.g., perpendicular) axes. Such a two-degree-of-freedom linear actuator may, in various implementations, move the sample holder 102 along a first axis relative to the resonator 110 as well as along a second axis thereby adjusting the position of the sample holder 102 relative to the resonator 110 along the second axis. In other implementations, the actuator system 112 could include, for example a three-degree-of-freedom actuator that moves the sample transfer device 106 along two linear axes and rotates the sample transfer device 106 about an axis of the sample transfer device 106. In various implementations, the actuator system 112 may be coupled to a position control system 115 that controls operation of the actuator system 112. In various implementations, the position control system 115 may be, for example, an automated control system such as, for example, a CNC control system, a PID control system, or other type of controller. In some cases, the position control system 115 may include, or may be implemented as, software or firmware running on a computer system (e.g., a microprocessor or another type of data processing apparatus). In some instances, the control mechanism may be a manual control such as, for example, a caliper or hand crank.

In the example shown in FIG. 1, the resonator 110, the sample holder 102, the attachment mechanism 108, and the first end of the sample transfer device 106 are disposed in a chamber 114. In various implementations, all or part of the chamber 114 may be a controlled environment that is cooled by a cooling system or pumped by a vacuum system, while the second end of the of the sample transfer device 106 is disposed outside the chamber 114. The sample transfer device 106 is introduced to the chamber 114 via an insertion point 113. In various embodiments, the insertion point 113 includes a seat 125 that defines an opening into the chamber 114. A centering device 123 is disposed around the sample transfer device 106 and mates with the seat 125 to create a pressure seal. In various implementations, an opening in the seat 125 is coupled to a load lock assembly 127. In this manner, the insertion point 113 may provide a vacuum-pressure environment or a low pressure gas seal between a controlled environment within the chamber 114 and a room temperature environment outside the chamber 114. In various implementations, the vacuum-pressure environment may be in the range of 1 micro-Torr to several hundred milli-Torr pressure. In various implementations, the cooling system maintains a cryogenic thermal environment within the chamber 114 for the resonator 110 and the sample holder 102. In some cases, the cooling system can maintain a cryogenic temperature of the resonator 110 and the sample holder 102. In the example shown in FIG. 1, the cooling system resides in thermal contact with the resonator 110 and the sample holder 102. In some cases, the cooling system cools to liquid helium temperatures (e.g., approximately 4 Kelvin), liquid nitrogen temperatures (e.g., approximately 77 Kelvin), or to another cryogenic temperature. In some cases, the cooling system includes a dry cryostat. In some cases, the cooling system can be implemented with or without the use of liquid cryogens, for example, as a continuous flow helium or nitrogen cryostat (e.g., 4-300 Kelvin), as a variable temperature pulsed-tube refrigerator (e.g., 3.5-300 Kelvin), a pumped helium cryostat (e.g., 1-10 Kelvin), a helium-3 refrigerator (e.g., 250-400 milliKelvin), a dilution refrigerator (e.g., 5-100 milliKelvin), or another type of system or combination of systems. In some implementations, the resonator 110 and the sample holder 102 are both held at cryogenic temperatures. In some cases, the resonator 110 and the sample holder 102 are immersed in a cryogenic liquid or a cryogenic gas, and may be held in a vacuum-pressure environment during operation. In some cases, the sample holder 102, the resonator 110, or both are held at a higher temperature (e.g., room temperature, etc.).

In the example shown in FIG. 1, a primary magnet system 116 generates a primary magnetic field that the resonator 110 and the sample holder 102 are exposed to during operation. In various implementations, the primary magnet system 116 may be located within the cooling system or outside of the cooling system. The primary magnet system 116 generates a magnetic field in the controlled environment of the resonator 110 and the sample holder 102. The example primary magnet system 116 shown in FIG. 1 can be implemented as a superconducting solenoid, an electromagnet, a permanent magnet or another type of magnet that generates the primary magnetic field. In various implementations, the magnetic field is homogeneous to under 100 ppm over the volume of a sample region defined by the resonator 110 or has a target spatial profile that includes design inhomogeneity. In some instances, a gradient system generates one or more gradient fields that spatially vary over the sample volume. In some cases, the gradient system includes multiple independent gradient coils that can generate gradient fields that vary along different spatial dimensions of the sample region.

In the example shown in FIG. 1, a spin ensemble in the sample region of the resonator 110 interacts with the resonator 110. The primary magnetic field generated by the primary magnet system 116 quantizes the spin states and sets the Larmor frequency of the spin ensemble. Control of the spin magnetization can be achieved, for example, by a radio-frequency or microwave electromagnetic field generated by the resonator 110. In the example shown in FIG. 1, the spin ensemble can be any collection of particles having non-zero spin that interact magnetically with the applied fields of the magnetic resonance system 100. For example, the spin ensemble can include nuclear spins, electron spins, or a combination of nuclear and electron spins. Examples of nuclear spins include hydrogen nuclei (¹H), carbon-13 nuclei (¹³C), and others. In some implementations, the spin ensemble is a collection of identical spin-½ free electron spins attached to an ensemble of large molecules.

In the example shown in FIG. 1, the resonator 110 is electrically coupled to a spectrometer system 118. In various implementations, the spectrometer system 118 acquires magnetic resonance data based on magnetic resonance signals generated by an interaction between the resonator 110 and magnetic resonance samples contained in the sample holder 102. Typically, the resonator 110 has one or more resonance frequencies and possibly other resonance frequencies or modes. The drive frequency can be tuned to the spins' resonance frequency, which is determined by the strength of the primary magnetic field and the gyromagnetic ratio of the spins.

The example spectrometer system 118 can control the resonator 110 and possibly other components or subsystems in the magnetic resonance system 100 shown in FIG. 1. The spectrometer system 118 is electromagnetically coupled to (e.g., by coaxial cables, waveguides, etc.), and adapted to communicate with, the resonator 110. For example, the spectrometer system 118 can be adapted to provide a voltage or current signal that drives the resonator 110; the spectrometer system 118 can also acquire a voltage or current signal from the resonator 110.

In some cases, the spectrometer system 118 includes or is connected with a controller, a waveform generator, an amplifier, a transmitter/receiver switch, a receiver, a signal processor, and possibly other components. A spectrometer system 118 can include additional or different features (e.g., a gradient waveform generator, and gradient electronics, etc.). In the example shown in FIG. 1, the spectrometer system 118 is adapted to communicate with, and may operate based on inputs provided by, one or more external sources, for example, a computer system or another source.

In some cases, the spectrometer system 118 may operate in multiple modes of operation. In one mode of operation, the spectrometer system 118 generates control signals (e.g., radio frequency signals, microwave signals, etc.) that are delivered to the resonator 110 to control the spin system in the sample. In another mode of operation, the spectrometer system 118 acquires magnetic resonance signals from the resonator 110. The magnetic resonance signals can be processed (e.g., digitized) and provided to a computer system for analysis, display, storage, or another action. The computer system may include one or more digital electronic controllers, microprocessors or other types of data-processing apparatus. The computer system may include memory, processors, and may operate as a general-purpose computer, or the computer system may operate as an application-specific device.

In some aspects of operation, the sample holder 102 is transferred between a sample loading region outside the chamber 114 and a sample region defined by the resonator 110. For example, the sample holder 102 may be transferred into the chamber 114 to load a new sample in the magnetic resonance system for measurement, or the sample holder may be transferred out of the chamber 114 to remove a sample after measurements have been obtained. In either case, the sample transfer device 106 is driven by the actuator system 112, which is controlled by the position control system 115.

In the example shown, when the sample holder 102 is to be loaded into the chamber 114, the sample transfer device 106 engages the sample holder 102 in a sample loading region outside the chamber 114. The centering device 123 is concentrically arranged on the sample transfer device 106 and mates with the seat 125, which aligns the sample holder 102 with an opening into the load lock assembly 127, so that the sample holder can be moved through the opening into the load lock assembly 127. When the sample holder 102 moves into the load lock assembly 127, the insertion point 113 becomes sealed (e.g., by mechanical contact between one or more of the centering device 123, the seat 125 and the sample transfer device 106). The load lock assembly 127 is then pumped to a pressure (e.g., a vacuum pressure) that more closely matches the environment of the sample region. A valve of the load lock assembly 127 is then opened so that the sample holder 102 can be moved to the sample region. The magnetic resonance system can then operate (e.g., in a pulsed mode, continuous wave mode, or another mode of operation) to obtain magnetic resonance measurements of the sample in the sample region. The sample holder 102 can then be removed from the chamber 114. For example, the sample holder 102 can be transferred through the valve of the load lock assembly 127, through the opening in the seat 125, to the sample loading region.

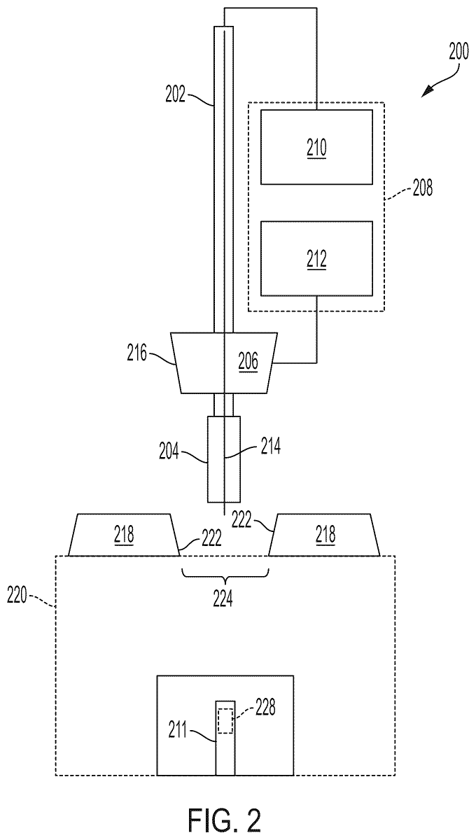

FIG. 2 is a schematic diagram of an example sample loading system 200 with a sample transfer device 202 in a first position. The sample holder 204 is coupled to a first end of the sample transfer device 202. In various implementations, the sample transfer device 202 receives the sample holder 204 in a sample loading region that is exposed to room temperature and pressure. A centering device 206 is disposed around the sample transfer device 202. The second end of the sample transfer device 202 is coupled to an actuator system 208 and the centering device 206 is coupled to the actuator system 208. In various implementations, the actuator system 208 may include a first actuator 210 that is coupled to the sample transfer device 202 and a second actuator 212 that is coupled to the centering device 206. In various implementations, the actuator system 208 may be the actuator system 112 described above with respect to FIG. 1 and the first actuator 210 and the second actuator 212 may be of any of the actuator types described above with respect to FIG. 1. During operation, the first actuator 210 and the second actuator 212 operate in concert to move the sample transfer device 202 and the centering device 206 in a linear fashion along an axis 214 of the sample transfer device 202.

The centering device 206 in various implementations has the shape of an inverted frustum and includes a mating surface 216. In the example shown, the mating surface 216 is an exterior lateral surface of the centering device 206. In various implementations, a first seal such as, for example, a gasket or an O ring may be disposed on the mating surface 216. In some cases, a second seal is disposed on an interior surface of the centering device 206 (e.g., a surface that defines a central orifice through the centering device 206) and creates a pressure seal between the centering device 206 and the sample transfer device 202. The sample transfer device 202 is able to move in a sliding fashion through a central orifice in the centering device 206.

A seat 218 is disposed on an outer surface of a chamber 220. The seat 218 includes a mating surface 222 that is complementary to the mating surface 216 on the centering device 206. An opening 224 that is defined by the seat 218 provides access to a chamber 220, which houses the resonator 211. A sample region 228 is defined by the resonator 211 in the primary magnetic field generated by the primary magnet system 116. During operation, engagement of the centering device 206 with the seat 218 causes the sample transfer device 202 to be aligned with the opening. In various implementations, the chamber 220 may be subjected to one or both of cryogenic temperatures or partial vacuum pressure. In particular, the chamber 220 may be under the temperature and pressure described above with respect to FIG. 1.

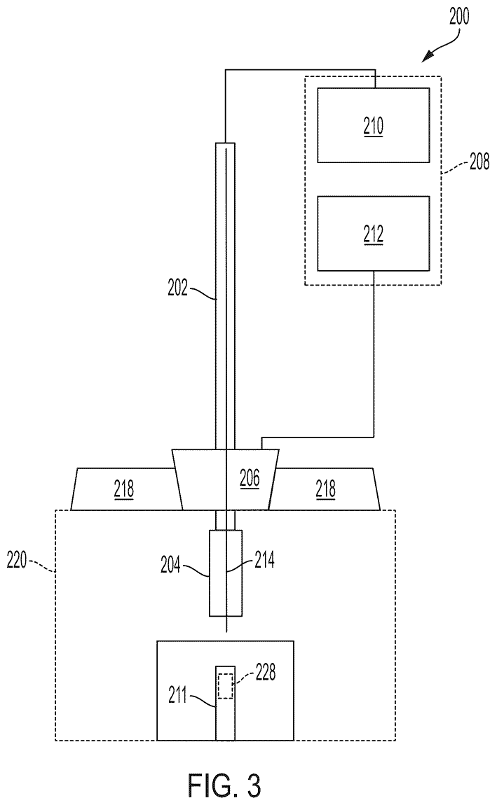

FIG. 3 is a schematic diagram of the example sample loading system 200 with the sample transfer device 202 in a second position. During operation, the first actuator 210 acts on the sample transfer device 202 to move the sample transfer device 202 and the sample holder 204 towards the seat. In implementations where the first actuator 210 is a linear actuator, the sample transfer device 202 and the sample holder 204 are moved in a linear manner. The second actuator 212 moves the centering device 206 with the sample transfer device 202. In various implementations, the sample transfer device 202 and the centering device 206 are moved at the same rate; however, in other implementations, the centering device 206 may be moved at a rate that is higher or lower than the sample transfer device 202. The sample holder 204 and the first end of the sample transfer device 202 pass through the opening 224 the is defined by the seat 218. The centering device 206 engages the seat 218, and the complementary mating surfaces (216 and 222) interact with each other to cause the sample transfer device 202 to be centered in the opening 224. Such centering aligns the sample holder 204 for positioning in the sample region, and allows the sample holder 204 to pass through the opening without mechanical interference. In various implementations, the sample holder 204 is aligned with the sample region with micron precision over the length of travel of the sample transfer device 202. In various implementations, the sample holder is aligned with the sample region with a tolerance of +/−10 μm.

In implementations where the chamber 220 is under cryogenic temperatures and/or partial vacuum pressure, a pressure seal, such as an O ring is disposed in the opening 524 and bears against the sample transfer device 502. Such a seal can prevent loss of pressure and/or preserve the cryogenic environment within the chamber 220. In other implementations, the seal may be disposed on one or more of the mating surface 222 of the seat 218 or the mating surface 216 of the centering device 206. In such an arrangement, the centering device 506 engages the seat 518 to align the sample transfer device 502. The sample holder 204 passes through the O-ring and through the opening 224. The sample transfer device 202 continues to descend until the sample transfer device passes through the O-ring, thereby creating a seal between the sample transfer device 202 and the O-ring. In various implementations, the sample holder 204 enters a load lock, where temperature and pressure are reduced to more closely match the pressure of the chamber 220. A valve in the load lock is then opened and the sample holder 204 continues to descend until it enters the sample region 228.

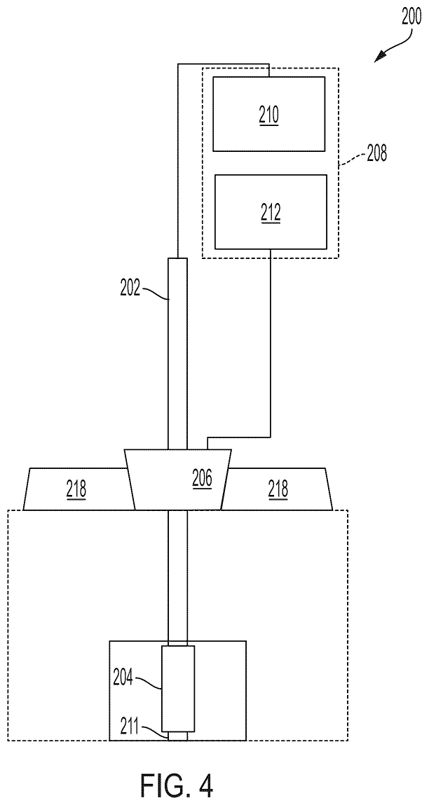

FIG. 4 is a schematic diagram of the example sample loading system 200 with the sample transfer device 202 in a third position. After the centering device 206 engages with the seat 218, the second actuator 212 ceases movement of the centering device 206. The first actuator 210 continues to move the sample transfer device 202 through the centering device 206 until the sample holder 204 is positioned in the sample region of the resonator 211.

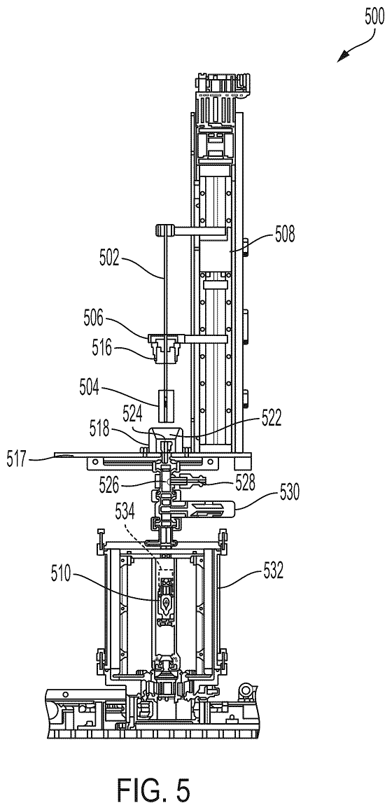

FIG. 5 is a cross-sectional view of an example magnetic resonance system 500 showing a sample transfer device 502 in a first position. In various implementations, the magnetic resonance system 500 may be similar to the magnetic resonance system 200 described above with respect to FIGS. 2-4. A sample holder 504 is coupled to a first end of the sample transfer device 502. A centering device 506 is disposed around the sample transfer device 502. The second end of the sample transfer device 502 is coupled to an actuator system 508 and the centering device is coupled to the actuator system 508. In various implementations, the actuator system 508 may include a first actuator that is coupled to the sample transfer device 502 and a second actuator that is coupled to the centering device 506. In various implementations the actuator system 508 may be the actuator system 112 described above with respect to FIG. 1 and the first actuator and the second actuator may be of any of the actuator types described above with respect to FIG. 1. During operation, the actuator system 508 moves the sample transfer device 502 and the centering device 206 in a linear fashion along an axis 514 of the sample transfer device 502.

The centering device 506 in various implementations has the shape of an inverted frustum and includes a mating surface 516. In various implementations, a first seal such as, for example, a gasket or an O-ring may be disposed on the mating surface 516. A second seal (not explicitly shown) is disposed on an interior surface of the seat 518 and creates a pressure seal between the seat 518 and the sample transfer device 502. The sample transfer device 502 is able to move in a sliding fashion through a central orifice in the centering device 506.

A seat 518 is disposed on an upper surface of a stage 517. An area above the seat 518 and the stage 517 provides a sample loading region of the magnetic resonance system 500. In some implementations, the sample loading region is exposed to room temperature and pressure. The seat 518 includes a mating surface 522 that is complementary to the mating surface 516 formed on the centering device 506. An opening 524 that is defined by the seat 518 provides access to a load lock assembly 526, which is disposed below the stage 517. The load lock 526 includes a port 528, which is fluidly coupled to a vacuum pump. A valve 530 is positioned between the load lock 526 and a chamber 532, which houses the resonator 510. A sample region 534 is defined near the resonator 510 by the primary magnetic field of the primary magnet system 116. During operation, engagement of the centering device 506 with the seat 518 causes the sample transfer device 502 to be aligned with the sample region. In various implementations, the sample holder 504 is aligned with the sample region with micron precision over the length of travel of the sample transfer device 502. In various implementations, the chamber 532 may be subjected to one or both of cryogenic temperatures or partial vacuum pressure. In particular, the chamber 532 may be under the temperature and pressure described above with respect to FIG. 1.

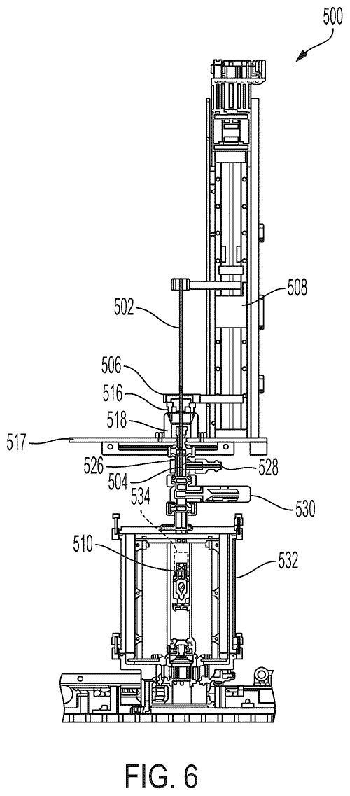

FIG. 6 is a cross-sectional view of the example magnetic resonance system 500 with the sample transfer device 502 in a second position. During operation, the actuator system 508 acts on the sample transfer device 502 to move the sample transfer device 502 and the sample holder 504 towards the seat 518. The actuator system 508 moves the centering device 506 with the sample transfer device 502. In various implementations, the sample transfer device 502 and the centering device 506 are moved at the same rate; however, in other implementations, the centering device 506 may be moved at a rate that is higher or lower than the sample transfer device 502. The sample holder 504 and the first end of the sample transfer device 502 pass through the opening 524 the is defined by the seat 518. The centering device 506 engages the seat 518. The complementary mating surfaces (516 and 522) interact with each other to cause the sample transfer device 502 to be centered in the opening 524. Such centering aligns the sample holder 504 for positioning in the sample region. In various implementations, the sample holder 504 is aligned with the sample region with micron precision over the length of travel of the sample transfer device 502.

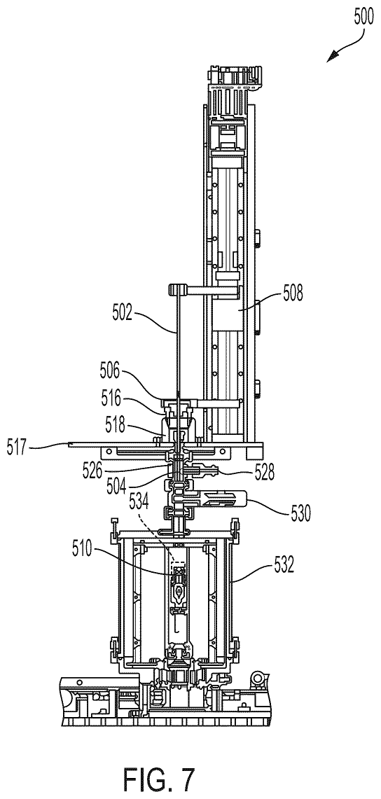

FIG. 6 is a cross-sectional view of the example magnetic resonance system 500 showing the sample transfer device 502 in the second position with a valve 530 closed. FIG. 7 is a cross-sectional view of the example magnetic resonance system 500 showing the sample transfer device 502 in the second position with the valve 530 open. After passing through the opening 524, the sample holder 504 enters the load lock assembly 526. Interaction of the sample transfer device 502 with the seat 518 seals the opening 524. The valve 530 is in the closed position. In various implementation, the valve 530 is a gate valve; however, in other implementations, the valve 530 may be, for example, a ball valve, a globe valve, a butterfly valve, a plug valve, a needle valve, or another type of valve. In various implementations, the valve 530 may be mechanically actuated; however, in other implementations the valve 530 may be electronically controlled. The vacuum pump applies a negative pressure differential to the port 528 to cause the internal pressure of the load lock 526 to more closely match the pressure of the chamber 532. Once the pressure in the load lock 526 more closely matches the pressure in the chamber 532, the valve 530 is moved to the open position. The actuator system 508 then continues to move the sample holder 504 through the valve 530 and into the chamber 532.

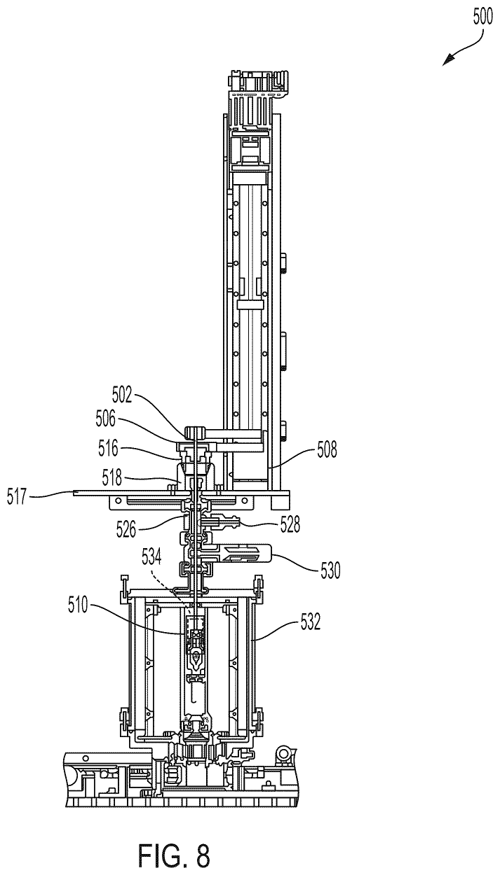

FIG. 8 is a cross-sectional view of the example magnetic resonance system 500 showing the sample transfer device 502 in a third position. After the centering device 506 engages with the seat 518, the second actuator system 508 ceases movement of the centering device 506. The actuator system 508 continues to move the sample transfer device 502 through the centering device 506 until the sample holder 504 is positioned in the sample region of the resonator 510.

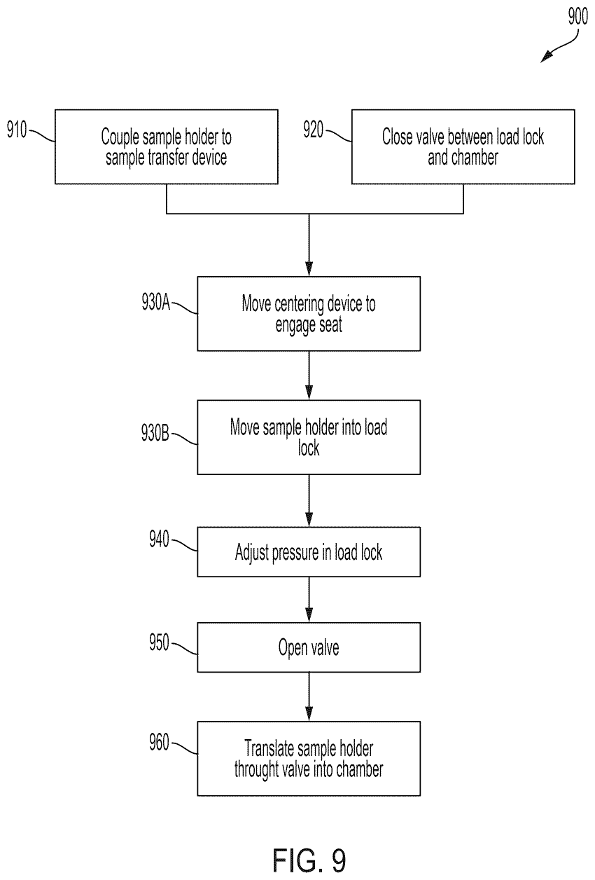

FIG. 9 is a flow diagram of an example process 900 for loading a sample in a magnetic resonance system. In various implementations, the magnetic resonance system is the example magnetic resonance system 500 discussed above with respect to FIGS. 5-8, the example magnetic resonance system 200 discussed above with respect to FIGS. 2-4 or another type of magnetic resonance system. The example process 900 may include additional or different operations, and the operations may be performed in the order shown or in another order. In some cases, one or more operations may be repeated, omitted, or performed in another manner.

At 910, a sample holder is coupled to a sample transfer device. The sample holder can be, for example, the example sample holder 102 shown in FIG. 1, the sample holder 202 described in FIGS. 2-4, the sample holder 504 described in FIGS. 5-8, or another type of sample holder. In various implementations the coupling of the sample holder to the sample transfer device occurs in a sample loading region of the magnetic resonance system. In various implementations, the sample loading region is exposed to room temperature and pressure.

As shown at 920, a valve between a load lock assembly and a chamber is initially in a closed position. Closure of the valve 530 maintains partial vacuum pressure within the chamber 534. In various implementations, the valve can be the valve 530 described in FIGS. 5-8 or another valve. The load lock assembly may be the load lock assembly 526 described in FIGS. 5-8 or another load lock assembly. In various implementations, closure of the valve creates a seal between an interior volume of the load lock assembly and the chamber.

At 930A, an actuator system causes the centering device to engage with the seat, which aligns the sample transfer device with an opening defined by the seat. In various implementations, the seat may be the seat 218 described in FIGS. 2-4, the seat 518 described in FIGS. 5-8, or another seat. Interaction of the centering device with the seat causes the sample holder and the sample transfer device to be centered in the opening and aligned with a sample region associated with a resonator. In various implementations, interaction of the centering device with the seat may seal the opening to the load lock. At 930B, after the sample transfer device is aligned with the opening, the actuator system also causes the sample transfer device to move the sample holder through the opening defined by the seat. After moving through the seat, the sample holder enters the interior volume of the load lock assembly.

At 940, an internal pressure of the load lock assembly is adjusted closer to an internal pressure of the chamber. In various implementations, the chamber is the chamber 114 described in FIG. 1, the chamber 220 described in FIGS. 2-4, the chamber 532 described in FIGS. 5-8 or another chamber. In various implementations, the interior environment of the chamber may be subject to one of cryogenic temperatures or partial vacuum pressure. Internal pressure of the load lock assembly may be adjusted via a port (e.g., the port 528) formed in the load lock assembly. For example, a vacuum pump may be coupled to the port to remove gas from the interior volume of the load lock assembly.

At 950, the valve is opened to allow passage of the sample holder from the load lock into the chamber. At 960, the sample holder is translated into the chamber. In some cases, interaction of the centering device with the seat causes the sample holder to be properly aligned with the sample region defined by the resonator. In various implementations, the sample holder is aligned with micron precision placement.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple embodiments separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. For example, in various implementations, a guide system may be utilized to facilitate insertion and placement of the sample holder within the resonator package and to prevent breakage of the sample holder. Such a guide system may include, for example rails that support opposite edges of the sample holder during placement. Accordingly, other embodiments are within the scope of the following claims.

1. A magnetic resonance system, comprising:
a primary magnet that generates a primary magnetic field;
a resonator that defines a sample region in the primary magnetic field;
a sample transfer arm comprising a first end configured to couple to a sample holder and translate the sample holder between a sample loading region and the sample region;
a centering device disposed around the sample transfer arm;
a seat that defines an opening;
an actuator system configured to:
move the centering device to mate with the seat, wherein mating the centering device with the seat aligns the sample holder with the opening; and
move the sample transfer arm to transfer the sample holder from the sample loading region, through the opening, towards the sample region.

2. The magnetic resonance system of claim 1, wherein the actuator system comprises:
a first actuator that moves the sample transfer arm; and
a second actuator that moves the centering device.

3. The magnetic resonance system of claim 1, wherein mating of the centering device with the seat aligns the sample holder with the sample region with micron precision placement.

4. The magnetic resonance system of claim 1, wherein the centering device comprises a seal that bears against the seat when the centering device is mated with the seat.

5. The magnetic resonance system of claim 4, comprising a load lock assembly coupled to the seat such that the opening creates a passage between the sample loading region and an interior volume of the load lock assembly.

6. The magnetic resonance system of claim 5, comprising a vacuum pump coupled to the load lock assembly and configured to pump fluid from the interior volume of the load lock assembly.

7. The magnetic resonance system of claim 5, comprising a magnetic resonance chamber coupled to the load lock assembly such that a passage is defined from the opening, through the interior volume of the load lock assembly, and into the magnetic resonance chamber, wherein the resonator resides in the magnetic resonance chamber.

8. The magnetic resonance system of claim 7, wherein the magnetic resonance chamber is disposed in a cryogenic environment.

9. The magnetic resonance system of claim 7, comprising a gate valve disposed between the load lock assembly and the magnetic resonance chamber.

10. The magnetic resonance system of claim 1, wherein the sample loading region is exposed to room temperature and pressure.

11. A method for loading a magnetic resonance sample, the method comprising:
coupling a sample transfer arm to a sample holder in a sample loading region of a magnetic resonance system;
by operation of an actuator system, moving a centering device to mate with a seat, wherein the centering device is disposed about the sample transfer arm and mating the centering device with the seat aligns the sample holder with an opening defined by the seat; and
by operation of the actuator system, moving the sample holder from the sample loading region, through the opening, towards a sample region defined by a resonator in a primary magnetic field of the magnetic resonance system.

12. The method of claim 11, wherein the actuator system comprises:
a first actuator that moves the sample transfer arm; and
a second actuator that moves the centering device.

13. The method of claim 11, wherein the centering device comprises a seal, and mating the centering device with the seat causes the seal to bear against the seat.

14. The method of claim 13, wherein moving the sample holder comprises moving the sample holder from the sample loading region, through the opening, into an interior volume of a load lock assembly.

15. The method of claim 14, comprising pumping fluid from the interior volume of the load lock assembly while the sample holder resides in the interior volume.

16. The method of claim 15, comprising, after pumping fluid from the interior volume, opening a gate valve between the interior volume of the load lock assembly and a magnetic resonance chamber, wherein the resonator resides in the magnetic resonance chamber.

17. The method of claim 16, wherein moving the sample holder comprises moving the sample holder from the interior volume of the load lock assembly, through the gate valve, into the magnetic resonance chamber.

18. The method of claim 11, wherein mating of the centering device with the seat aligns the sample holder with the sample region with micron precision placement.

19. The method of claim 11, wherein the magnetic resonance chamber is disposed in a cryogenic environment.

20. The method of claim 11, wherein the sample loading region is disposed in exposed to room temperature and pressure.
